(19) United States
(12) Patent Application Publication
(10) Pub. No.: US 2023/0093365 A1
(43) Pub. Date: Mar. 23, 2023

(54) SEMICONDUCTOR MANUFACTURING APPARATUS

(71) Applicants: KABUSHIKI KAISHA TOSHIBA, Tokyo (JP); TOSHIBA ELECTRONIC DEVICES & STORAGE CORPORATION, Tokyo (JP)

(72) Inventor: Atsuro INADA, Nonoichi (JP)

(73) Assignees: KABUSHIKI KAISHA TOSHIBA, Tokyo (JP); TOSHIBA ELECTRONIC DEVICES & STORAGE CORPORATION, Tokyo (JP)

(21) Appl. No.: 17/653,180

(22) Filed: Mar. 2, 2022

(30) Foreign Application Priority Data
Sep. 22, 2021 (JP) 2021-154479

(51) Int. Cl. H01L 21/67; C23C 16/52; C23C 16/455

(52) U.S. Cl. CPC H01L 21/67069; C23C 16/52; C23C 16/45561; H01L 21/78

(57) ABSTRACT

A semiconductor manufacturing apparatus includes: a first storage container storing a first raw material and having a first container outlet; a reaction chamber; a first flow rate controller adjusting a flow rate of the first raw material transported from the first container outlet of the first storage container to the reaction chamber and having a first inlet and a first outlet; a first pipe connecting the first container outlet of the first storage container and the first inlet of the first flow rate controller to each other and having a first connection portion; a second pipe connecting the first outlet of the first flow rate controller and the reaction chamber to each other and having a second connection portion having a first flow path switching valve; a third pipe connected to the first pipe at the first connection portion and connected to the second pipe at the second connection portion; a first pump having a first intake port connected to a portion of the third pipe connected to the second connection portion, the first pump having a first exhaust port connected to a portion of the third pipe connected to the first connection portion and the first pump transporting the first raw material from the second pipe to the first pipe; and a second flow rate controller having a second inlet connected to a portion of the third pipe between the first connection portion and the first pump, the second inlet being connected to the first pump, the second flow rate controller having a second outlet connected to a portion of the third pipe between the first connection portion and the first pump, the second outlet being connected to the first connection portion and the second flow rate controller controlling the flow rate of the first raw material supplied from the first pump to the first flow rate controller.

### CROSS-REFERENCE TO RELATED APPLICATION

This application is based upon and claims the benefit of priority from Japanese Patent Application No. 2021-154479, filed on Sep. 22, 2021, the entire contents of which are incorporated herein by reference.

### FIELD

Embodiments described herein relate generally to a semiconductor manufacturing apparatus.

### BACKGROUND

A semiconductor device, such as a semiconductor chip, is manufactured by carrying a substrate, such as a semiconductor substrate, into a reaction chamber and supplying a raw material.

### BRIEF DESCRIPTION OF THE DRAWINGS

FIG. 1 is a schematic diagram of a semiconductor manufacturing apparatus of embodiments;

FIG. 2 is a schematic diagram showing an aspect of a second connection portion of embodiments;

FIG. 3 is a schematic diagram showing an aspect of a fourth connection portion of embodiments; and

FIGS. 4A to 4C are schematic cross-sectional views showing an aspect of a semiconductor device manufacturing process using the semiconductor manufacturing apparatus of embodiments.

### DETAILED DESCRIPTION

A semiconductor manufacturing apparatus of embodiments includes: a first storage container storing a first raw material and having a first container outlet; a reaction chamber; a first flow rate controller adjusting a flow rate of the first raw material transported from the first container outlet of the first storage container to the reaction chamber and having a first inlet and a first outlet; a first pipe connecting the first container outlet of the first storage container and the first inlet of the first flow rate controller to each other and having a first connection portion; a second pipe connecting the first outlet of the first flow rate controller and the reaction chamber to each other and having a second connection portion having a first flow path switching valve; a third pipe connected to the first pipe at the first connection portion and connected to the second pipe at the second connection portion; a first pump having a first intake port connected to a portion of the third pipe connected to the second connection portion, the first pump having a first exhaust port connected to a portion of the third pipe connected to the first connection portion and the first pump transporting the first raw material from the second pipe to the first pipe; and a second flow rate controller having a second inlet connected to a portion of the third pipe between the first connection portion and the first pump, the second inlet being connected to the first pump, the second flow rate controller having a second outlet connected to a portion of the third pipe between the first connection portion and the first pump, the second outlet being connected to the first connection portion and the second flow rate controller controlling the flow rate of the first raw material supplied from the first pump to the first flow rate controller.

Hereinafter, embodiments will be described with reference to the diagrams. In the following description, the same members and the like are denoted by the same reference numerals, and the description of the members and the like once described will be omitted as appropriate.

### Embodiments

A semiconductor manufacturing apparatus of embodiments is a semiconductor manufacturing apparatus including: a first storage container storing a first raw material and having a first container outlet; a reaction chamber; a first flow rate controller adjusting a flow rate of the first raw material transported from the first container outlet of the first storage container to the reaction chamber and having a first inlet and a first outlet; a first pipe connecting the first container outlet of the first storage container and the first inlet of the first flow rate controller to each other and having a first connection portion; a second pipe connecting the first outlet of the first flow rate controller and the reaction chamber to each other and having a second connection portion having a first flow path switching valve; a third pipe connected to the first pipe at the first connection portion and connected to the second pipe at the second connection portion; a first pump having a first intake port connected to a portion of the third pipe connected to the second connection portion, the first pump having a first exhaust port connected to a portion of the third pipe connected to the first connection portion and the first pump transporting the first raw material from the second pipe to the first pipe; and a second flow rate controller having a second inlet connected to a portion of the third pipe between the first connection portion and the first pump, the second inlet being connected to the first pump, the second flow rate controller having a second outlet connected to a portion of the third pipe between the first connection portion and the first pump, the second outlet being connected to the first connection portion and the second flow rate controller controlling the flow rate of the first raw material supplied from the first pump to the first flow rate controller.

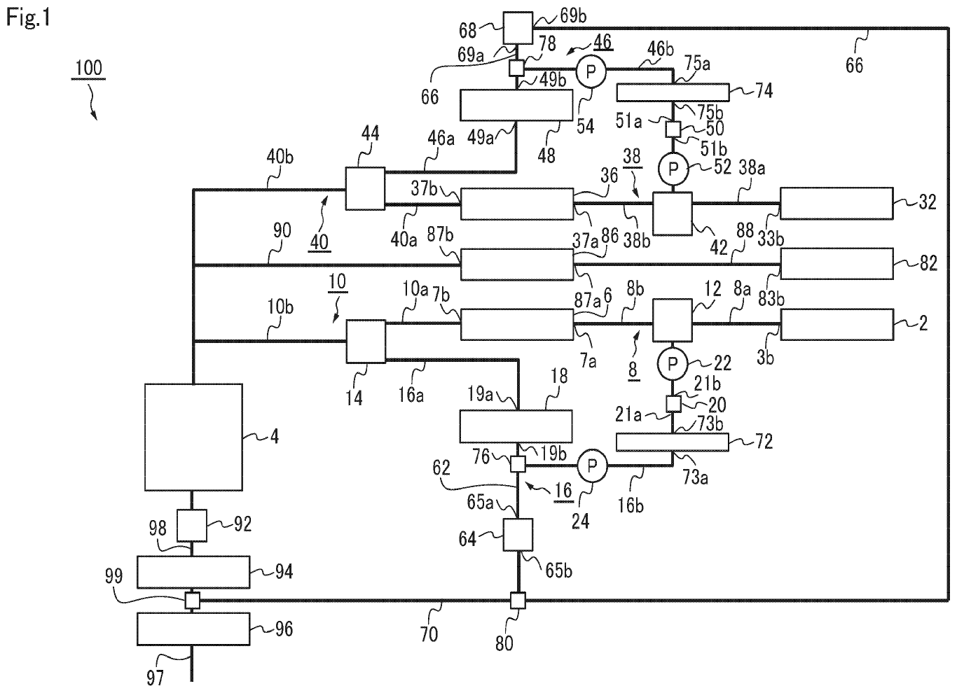

FIG. 1 is a schematic diagram of a semiconductor manufacturing apparatus 100 of embodiments.

The semiconductor manufacturing apparatus 100 of embodiments will be described with reference to FIG. 1.

The semiconductor manufacturing apparatus 100 is used for dry etching of a substrate used in the manufacturing of a semiconductor device, such as a metal-oxide-semiconductor field effect transistor (MOSFET), and thin film growth using a chemical vapor deposition (CVD) method, for example. However, the applications of the semiconductor manufacturing apparatus 100 are not limited to the above applications.

A first storage container 2 has a first container outlet 3b. The first storage container 2 stores a first raw material. A second storage container 32 has a second container outlet 33b. The second storage container 32 stores a second raw material. A fifth storage container 82 has a fifth container outlet 83b. The fifth storage container 82 stores a third raw material. The first raw material, the second raw material, and the third raw material may be, for example, a gas or a liquid, respectively.

The first raw material and the second raw material are preferably, for example, a fluorine-supplied etching gas and a fluorine hydrocarbon, respectively. The first raw material and the second raw material are preferably, for example, sulfur hexafluoride (SF₆) and octafluorocyclobutane (C₄F₀), respectively.

In addition, the first raw material is preferably, for example, trimethylaluminum (TMA), tetrakisdimethylamide titanium (TDMAT), or tetrakisdiethylaminohafnium (TDEAH). In such a case, the second raw material is preferably, for example, a water (H₂O) gas.

The third raw material is, for example, an inert gas such as an argon (Ar) gas or a nitrogen (N₂) gas used as a carrier gas for manufacturing a semiconductor device.

However, the first raw material, the second raw material, and the third raw material used in the semiconductor manufacturing apparatus 100 of embodiments are not particularly limited.

Inside a reaction chamber 4, for example, a substrate support unit (not shown) is provided. A substrate (not shown) is disposed on the substrate support unit. The above-described first raw material, second raw material, and third raw material are appropriately supplied onto the substrate. Then, for example, a semiconductor device is manufactured on the substrate.

In addition, a pipe 98 is connected to the reaction chamber 4. In the pipe 98, for example, a sixth flow rate adjustor 92 such as a butterfly valve and a third pump 94 such as a turbo molecular pump are provided. The pipe 98, a ninth pipe 70, and a pipe 97 are connected to each other by, for example, an eighth connection portion 99, which is a T-shaped pipe. A fourth pump 96, such as a dry pump, is appropriately provided in the pipe 97. Then, surplus raw materials and the like that have not been used in the manufacturing of the semiconductor device are discharged to the outside of the reaction chamber 4 via the pipe 98 and the pipe 97.

A first flow rate controller 6 has a first inlet 7a and a first outlet 7b. The first flow rate controller 6 controls the flow rate of the first raw material transported from the first storage container 2 to the reaction chamber 4. The first flow rate controller 6 is, for example, a mass flow controller. A first pipe 8 has a first pipe 8a and a first pipe 8b. The first pipe 8a and the first pipe 8b are connected to each other by, for example, a first connection portion 12. The first pipe 8a and the first pipe 8b connect the first container outlet 3b of the first storage container 2 and the first inlet 7a of the first flow rate controller 6 to each other. A second pipe 10 has a second pipe 10a and a second pipe 10b. The second pipe 10a and the second pipe 10b are connected to each other by, for example, a second connection portion 14. The second pipe 10a and the second pipe 10b connect the first outlet 7b of the first flow rate controller 6 and the reaction chamber 4 to each other.

A third pipe 16 has a third pipe 16a and a third pipe 16b. The third pipe 16a and the third pipe 16b are connected to each other. The third pipe 16b is connected to the first pipe 8a and the first pipe 8b at the first connection portion 12. The third pipe 16a is connected to the second pipe 10a and the second pipe 10b at the second connection portion 14.

The first connection portion 12 is connected to the first pipe 8a, the first pipe 8b, and the third pipe 16b. The first connection portion 12 is, for example, a T-shaped pipe.

The second connection portion 14 is connected to the second pipe 10a, the second pipe 10b, and the third pipe 16a. The second connection portion 14 allows a raw material flowing via the second pipe 10a to be supplied to the reaction chamber 4 or the third pipe 16a. In addition, the second connection portion 14 may allow a raw material flowing via the second pipe 10a to be supplied to both the reaction chamber 4 and the third pipe 16a. The second connection portion 14 is, for example, a three-way valve. The second connection portion 14 is, for example, a flow path switching valve. The second connection portion 14 is, for example, a change valve.

A first pump 18 has a first intake port 19a and a first exhaust port 19b. The first pump 18 is provided in the third pipe 16a. For example, the first intake port 19a of the first pump 18 is connected to a portion of the third pipe 16a connected to the second connection portion 14. In addition, the first exhaust port 19b of the first pump 18 is connected to a portion of the third pipe 16b connected to the first connection portion 12. The first pump 18 transports at least a part of the first raw material from the second pipe 10 to the first pipe 8.

The second flow rate controller 20 has a second inlet 21a and a second outlet 21b. The second flow rate controller 20 is provided in the third pipe 16b between the first connection portion 12 and the first pump 18. The second inlet 21a of the second flow rate controller 20 is connected to a portion of the third pipe 16b between the first connection portion 12 and the first pump 18 and the second inlet 21a is connected to the first pump 18. In addition, the second outlet 21b of the second flow rate controller 20 is connected to a portion of the third pipe 16b between the first connection portion 12 and the first pump 18 and the second outlet 21b is connected to the first connection portion 12. The second flow rate controller 20 adjusts the amount of the first raw material supplied from the first pump 18 to the first flow rate controller 6. The second flow rate controller 20 is not particularly limited. For example, a butterfly valve, a ball valve, a needle valve, a mass flow controller, a flow rate control valve, and a throttle valve can be preferably used.

A seventh pipe 62 can be connected to the third pipe 16. In other words, the seventh pipe 62 can be connected to a portion of the third pipe 16b between the first pump 18 and the second flow rate controller 20. The seventh pipe 62 discharges the first raw material to the outside of the third pipe 16 by, for example, the fourth pump 96. In FIG. 1, the seventh pipe 62 is connected to the eighth connection portion 99 between the third pump 94 and the fourth pump 96 via a seventh connection portion 80 connected to the seventh pipe 62 and the ninth pipe 70 connected via the seventh connection portion 80. Then, the first raw material discharged to the outside of the third pipe 16 is discharged by using the fourth pump 96. However, for example, the seventh pipe 62 may be connected to another pump (not shown), which is different from the third pump 94 and the fourth pump 96. Then, the first raw material discharged to the outside of the third pipe 16 may be discharged by using another pump (not shown). In addition, the connection of the seventh pipe 62, the third pipe 16a, and the third pipe 16b may be made by using, for example, a fifth connection portion 76 that is a T-shaped pipe, or may be made by using another method.

A first adjustor 64 has a fifth inlet 65a and a fifth outlet 65b. The first adjustor 64 is provided in the seventh pipe 62. The fifth inlet 65a of the first adjustor 64 is connected to the seventh pipe 62. The fifth outlet 65b of the first adjustor 64 is connected to the ninth pipe 70 via the seventh connection portion 80. The connection of the seventh pipe 62, the eighth pipe 66, and the ninth pipe 70 may be made by using, for example, the seventh connection portion 80 that is a T-shaped pipe, or may be made by using another method. The first adjustor 64 adjusts the amount of the first raw material discharged to the seventh pipe 62. The first adjustor 64 is not particularly limited. For example, a butterfly valve, a ball valve, a needle valve, a mass flow controller, a flow rate control valve, and a throttle valve can be preferably used. In addition, the first adjustor 64 may be a check valve that opens when the pressure in the third pipe 16 is too high so that the first raw material flows from the fifth inlet 65a to the fifth outlet 65b.

For example, the pressure on the secondary side (the second outlet 21b side or the first connection portion 12 side) of the second flow rate controller 20 is controlled so as to be the same as the pressure on the first raw material supply side (inside the first pipe 8). In addition, for example, the pressure on the primary side (the fifth inlet 65a side or the third pipe 16 side) of the first adjustor 64 is controlled so as to be higher than the pressure on the primary side (the second inlet 21a side or the second pressure gauge 24 side) of the second flow rate controller 20. As a result, the first raw material of an amount proportional to the difference between the pressure on the primary side of the first adjustor 64 and the pressure on the primary side of the second flow rate controller 20 can be stored inside the third pipe 16a, inside the third pipe 16b, and inside a third storage container 72.

The third storage container 72 has a third container inlet 73a and a third container outlet 73b. The third storage container 72 is provided in the third pipe 16b between the first pump 18 and the second flow rate controller 20. The third container inlet 73a of the third storage container 72 is connected to a portion of the third pipe 16b connected to the first pump 18. The portion of the third pipe 16b connected to the first pump 18 is provided between the first pump 18 and the second flow rate controller 20. The third container outlet 73b of the third storage container 72 is connected to a portion of the third pipe 16b connected to the second flow rate controller 20. The portion of the third pipe 16b connected to the second flow rate controller 20 is provided between the first pump 18 and the second flow rate controller 20. In other words, the third container inlet 73a of the third storage container 72 is connected to a portion of the third pipe 16b between the first pump 18 and the second flow rate controller 20. The third container inlet 73a is connected to the first pump 18. In addition, in other words, the third container outlet 73b of the third storage container 72 is connected to a portion between the first pump 18 and the second flow rate controller 20. The third container outlet 73b is connected to the second flow rate controller 20. The third storage container 72 stores the first raw material in the third pipe 16. The third storage container 72 does not have to be a container capable of applying high pressure to the inside, such as a compressed gas cylinder. For example, the third storage container 72 may have the third pipe 16 with a larger pipe diameter so that a larger amount of first raw material can be stored. In addition, the third storage container 72 may not be provided.

A first pressure gauge 22 is provided in the third pipe 16b between the first connection portion 12 and the second flow rate controller 20. The second pressure gauge 24 is provided in the third pipe 16b between the first pump 18 and the second flow rate controller 20 or the third storage container 72.

A third flow rate controller 36 has a third inlet 37a and a third outlet 37b. The third flow rate controller 36 controls the flow rate of the second raw material transported from the second storage container 32 to the reaction chamber 4. The third flow rate controller 36 is, for example, a mass flow controller. A fourth pipe 38 has a fourth pipe 38a and a fourth pipe 38b. The fourth pipe 38a and the fourth pipe 38b are connected to each other by, for example, a third connection portion 42. The fourth pipe 38a and the fourth pipe 38b connect the second container outlet 33b of the second storage container 32 and the third inlet 37a of the third flow rate controller 36 to each other. A fifth pipe 40 has a fifth pipe 40a and a fifth pipe 40b. The fifth pipe 40a and the fifth pipe 40b are connected to each other by, for example, a fourth connection portion 44. The fifth pipe 40a and the fifth pipe 40b connect the third outlet 37b of the third flow rate controller 36 and the reaction chamber 4 to each other.

A sixth pipe 46 has a sixth pipe 46a and a sixth pipe 46b. The sixth pipe 46a and the sixth pipe 46b are connected to each other. The sixth pipe 46b is connected to the fourth pipe 38a and the fourth pipe 38b at the third connection portion 42. The sixth pipe 46a is connected to the fifth pipe 40a and the fifth pipe 40b at the fourth connection portion 44.

The third connection portion 42 is connected to the fourth pipe 38a, the fourth pipe 38b, and the sixth pipe 46b. The third connection portion 42 is, for example, a T-shaped pipe.

The fourth connection portion 44 is connected to the fifth pipe 40a, the fifth pipe 40b, and the sixth pipe 46a. The fourth connection portion 44 allows a raw material flowing via the fifth pipe 40a to be supplied to the reaction chamber 4 or the sixth pipe 46a. In addition, the fourth connection portion 44 may allow a raw material flowing via the fifth pipe 40a to be supplied to both the reaction chamber 4 and the sixth pipe 46a. The fourth connection portion 44 is, for example, a three-way valve. The fourth connection portion 44 is, for example, a flow path switching valve. The fourth connection portion 44 is, for example, a change valve.

A second pump 48 has a second intake port 49a and a second exhaust port 49b. The second pump 48 is provided in the sixth pipe 46. For example, the second intake port 49a of the second pump 48 is connected to a portion of the sixth pipe 46a connected to the fourth connection portion 44. In addition, the second exhaust port 49b of the second pump 48 is connected to a portion of the sixth pipe 46b connected to the third connection portion 42. The second pump 48 transports at least a part of the second raw material from the fifth pipe 40 to the fourth pipe 38.

The fourth flow rate controller 50 has a fourth inlet 51a and a fourth outlet 51b. The fourth flow rate controller 50 is provided in the sixth pipe 46b between the third connection portion 42 and the second pump 48. The fourth inlet 51a of the fourth flow rate controller 50 is connected to a portion of the sixth pipe 46b between the third connection portion 42 and the second pump 48 and the fourth inlet 51a is connected to the second pump 48. In addition, the fourth outlet 51b of the fourth flow rate controller 50 is connected to a portion of the sixth pipe 46b between the third connection portion 42 and the second pump 48 and the fourth outlet 51b is connected to the third connection portion 42. The fourth flow rate controller 50 adjusts the amount of the second raw material supplied from the second pump 48 to the third flow rate controller 36. The fourth flow rate controller 50 is not particularly limited. For example, a butterfly valve, a ball valve, a needle valve, a mass flow controller, a flow rate control valve, and a throttle valve can be preferably used.

The eighth pipe 66 can be connected to the sixth pipe 46b. In other words, the eighth pipe 66 can be connected to a portion of the sixth pipe 46b between the second pump 48 and the fourth flow rate controller 50. The eighth pipe 66 discharges the second raw material from the sixth pipe 46 to the outside of the semiconductor manufacturing apparatus 100 by, for example, the fourth pump 96. In FIG. 1, the eighth pipe 66 is connected to the eighth connection portion 99 via the seventh connection portion 80 and the ninth pipe 70. The seventh connection portion 80 is connected to the eighth pipe 66. The ninth pipe 70 is connected to the seventh connection portion 80. The eighth connection portion 99 is provided between the third pump 94 and the fourth pump 96. Then, the second raw material is discharged to the outside of the sixth pipe 46 by using the fourth pump 96. However, for example, the eighth pipe 66 may be connected to a pump (not shown), which is different from the third pump 94 and the fourth pump 96. Then, the second raw material discharged to the outside of the sixth pipe 46 may be discharged by using a pump (not shown). In addition, the connection of the eighth pipe 66, the sixth pipe 46a, and the sixth pipe 46b may be made by using, for example, a sixth connection portion 78 that is a T-shaped pipe, or may be made by using another method.

A second adjustor 68 has a sixth inlet 69a and a sixth outlet 69b. The second adjustor 68 is provided in the eighth pipe 66. The sixth inlet 69a of the second adjustor 68 is connected to the eighth pipe 66. The sixth outlet 69b of the second adjustor 68 is connected to the ninth pipe 70 via the seventh connection portion 80. The second adjustor 68 adjusts the amount of the second raw material discharged to the eighth pipe 66. The second adjustor 68 is not particularly limited. For example, a butterfly valve, a ball valve, a needle valve, a mass flow controller, a flow rate control valve, and a throttle valve can be preferably used. In addition, the second adjustor 68 may be a check valve that opens when the pressure in the sixth pipe 46 is too high so that the second raw material flows from the sixth inlet 69a to the sixth outlet 69b.

For example, the pressure on the secondary side (the fourth outlet 51b side or the third connection portion 42 side) of the fourth flow rate controller 50 is controlled so as to be the same as the pressure on the second raw material supply side (inside the fourth pipe 38). In addition, for example, the pressure on the primary side (the sixth inlet 69a side or the sixth pipe 46 side) of the second adjustor 68 is controlled so as to be higher than the pressure on the primary side (the fourth inlet 51a side or the fourth pressure gauge 54 side) of the fourth flow rate controller 50. As a result, the second raw material of an amount proportional to the difference between the pressure on the primary side of the second adjustor 68 and the pressure on the primary side of the fourth flow rate controller 50 can be stored inside the sixth pipe 46a, inside the sixth pipe 46b, and inside a fourth storage container 74.

The fourth storage container 74 has a fourth container inlet 75a and a fourth container outlet 75b. The fourth storage container 74 is provided in the sixth pipe 46b between the second pump 48 and the fourth flow rate controller 50. The fourth container inlet 75a of the fourth storage container 74 is connected to a portion of the sixth pipe 46b connected to the second pump 48. The portion of the sixth pipe 46b connected to the second pump 48 is provided between the second pump 48 and the fourth flow rate controller 50. The fourth container outlet 75b of the fourth storage container 74 is connected to a portion of the sixth pipe 46b connected to the fourth flow rate controller 50. The portion of the sixth pipe 46b connected to the fourth flow rate controller 50 is provided between the second pump 48 and the fourth flow rate controller 50. In other words, the fourth container inlet 75a of the fourth storage container 74 is connected to a portion of the sixth pipe 46b between the second pump 48 and the fourth flow rate controller 50. The fourth container inlet 75a is connected to the second pump 48. In addition, in other words, the fourth container outlet 75b of the fourth storage container 74 is connected to a portion between the second pump 48 and the fourth flow rate controller 50. The fourth container outlet 75b is connected to the fourth flow rate controller 50. The fourth storage container 74 stores the second raw material in the sixth pipe 46. The fourth storage container 74 does not have to be a container capable of applying high pressure to the inside, such as a compressed gas cylinder. For example, the fourth storage container 74 may have the sixth pipe 46 with a larger pipe diameter so that a larger amount of second raw material can be stored. In addition, the fourth storage container 74 may not be provided.

A third pressure gauge 52 is provided in the sixth pipe 46b between the third connection portion 42 and the fourth flow rate controller 50. The fourth pressure gauge 54 is provided in the sixth pipe 46b between the second pump 48 and the fourth flow rate controller 50 or the fourth storage container 74.

A fifth flow rate controller 86 has an inlet 87a and an outlet 87b. The fifth flow rate controller 86 controls the flow rate of the third raw material transported from the fifth storage container 82 to the reaction chamber 4. The fifth flow rate controller 86 is, for example, a mass flow controller. A tenth pipe 88 connects the fifth container outlet 83b of the fifth storage container 82 and the inlet 87a of the fifth flow rate controller 86 to each other. An eleventh pipe 90 connects the outlet 87b of the fifth flow rate controller 86 and the reaction chamber 4 to each other.

The fifth storage container 82, the fifth flow rate controller 86, the tenth pipe 88, and the eleventh pipe 90 may not be provided.

The internal volume of the third storage container 72 is preferably smaller than the volume of the fourth storage container 74.

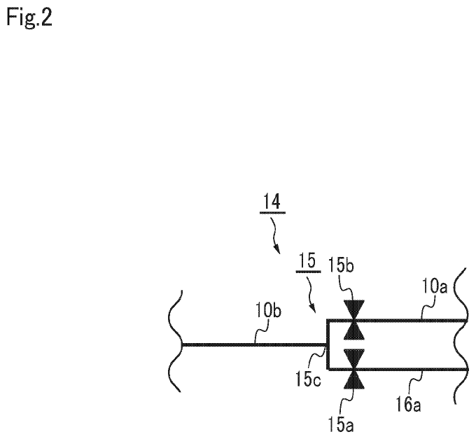

FIG. 2 is a schematic diagram showing an aspect of the second connection portion 14 of embodiments. The second connection portion 14 has a first flow path switching valve 15. Here, the first flow path switching valve 15 has a valve 15a, a valve 15b, and a connection portion 15c. The second pipe 10a, the second pipe 10b, and the third pipe 16a are connected to each other by a T-shaped pipe at the connection portion 15c. The valve 15b is provided in the second pipe 10a. In addition, the valve 15a is provided in the third pipe 16a. In addition, the aspects of the second connection portion 14 and the first flow path switching valve 15 are not limited to those shown in FIG. 2.

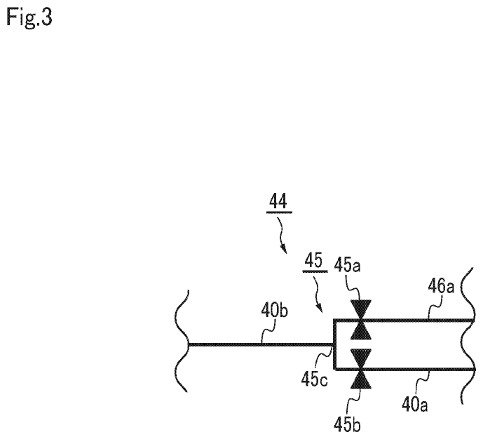

FIG. 3 is a schematic diagram showing an aspect of the fourth connection portion 44 of embodiments. The fourth connection portion 44 has a second flow path switching valve 45. Here, the second flow path switching valve 45 has a valve 45a, a valve 45b, and a connection portion 45c. The fifth pipe 40a, the fifth pipe 40b, and the sixth pipe 46a are connected to each other by a T-shaped pipe at the connection portion 45c. The valve 45b is provided in the fifth pipe 40a. In addition, the valve 45a is provided in the sixth pipe 46a. In addition, the aspects of the fourth connection portion 44 and the second flow path switching valve 45 are not limited to those shown in FIG. 3.

Next, a semiconductor device manufacturing method using the semiconductor manufacturing apparatus 100 of embodiments will be described.

The first raw material in the first storage container 2 is supplied to the inside of the reaction chamber 4 via the first pipe 8, the first connection portion 12, the first flow rate controller 6, the second pipe 10 and the second connection portion 14. Here, the second connection portion 14 is set so that, for example, the first raw material does not flow into the third pipe 16a. In addition, the second flow rate controller 20 is closed so that no raw material flows, for example. In addition, the third raw material in the fifth storage container 82 is supplied to the inside of the reaction chamber 4 via the tenth pipe 88, the fifth flow rate controller 86, and the eleventh pipe 90. The surplus first raw material and the surplus third raw material are discharged to the outside of the reaction chamber 4 via the sixth flow rate adjustor 92, the third pump 94 and the fourth pump 96.

Then, the second connection portion 14 is set so that, for example, the first raw material is transported to the third pipe 16a and not transported to the reaction chamber 4. The first raw material transported to the third pipe 16a is stored inside the third pipe 16a, inside the third pipe 16b, and inside the third storage container 72. When the third storage container 72 is not provided, the first raw material transported to the third pipe 16b is stored inside the third pipe 16a and inside the third pipe 16b. Here, it is preferable to measure the pressure in the third pipe 16b or the pressure in the third storage container 72 by using the second pressure gauge 24 and estimate the amount of the first raw material stored inside the third pipe 16b or inside the third storage container 72. In addition, when a large amount of first raw material is stored inside the third pipe 16b or inside the third storage container 72 and the pressure inside the third pipe 16b or inside the third storage container 72 is too high, a part of the first raw material stored inside the third pipe 16b or inside the third storage container 72 may be discharged by using the first adjustor 64.

In addition, the second raw material in the second storage container 32 is supplied to the inside of the reaction chamber 4 via the fourth pipe 38, the third connection portion 42, the third flow rate controller 36, the fifth pipe 40, and the fourth connection portion 44. Here, the fourth connection portion 44 is set so that, for example, the second raw material is not transported to the sixth pipe 46a. In addition, the fourth flow rate controller 50 is closed so that no raw material flows, for example. The surplus second raw material and the surplus third raw material are discharged to the outside of the reaction chamber 4 via the sixth flow rate adjustor 92, the third pump 94 and the fourth pump 96.

Then, the fourth connection portion 44 is set so that, for example, the second raw material is transported to the sixth pipe 46a and not transported to the reaction chamber 4. The second raw material transported to the sixth pipe 46a is stored inside the sixth pipe 46a, inside the sixth pipe 46b, and inside the fourth storage container 74. When the fourth storage container 74 is not provided, the second raw material transported to the sixth pipe 46b is stored inside the sixth pipe 46a and inside the sixth pipe 46b. Here, it is preferable to measure the pressure in the sixth pipe 46b or the pressure in the fourth storage container 74 by using the fourth pressure gauge 54 and estimate the amount of the second raw material stored inside the sixth pipe 46b and the fourth storage container 74. In addition, when a large amount of second raw material is stored inside the sixth pipe 46b or inside the fourth storage container 74 and the pressure inside the sixth pipe 46b or inside the fourth storage container 74 is too high, a part of the second raw material stored inside the sixth pipe 46b or inside the fourth storage container 74 may be discharged by using the second adjustor 68.

In addition, the first raw material in the first storage container 2 is supplied to the inside of the reaction chamber 4 via the first pipe 8, the first connection portion 12, the first flow rate controller 6, the second pipe 10, and the second connection portion 14. Here, the first raw material stored inside the third pipe 16a, the third pipe 16b, or the third storage container 72 is further supplied to the inside of the reaction chamber 4 via the second flow rate controller 20, the first connection portion 12, the first flow rate controller 6, the second pipe 10, and the second connection portion 14. For example, when the second flow rate controller 20 is a butterfly valve or the like, the opening degree of the butterfly valve or the like is appropriately controlled so that an appropriate amount of first raw material is transported to the reaction chamber 4 via the first flow rate controller 6. Here, for example, it is preferable to adjust the opening degree of the butterfly valve or the like by using the pressure of the third pipe 16b between the second flow rate controller 20 and the first connection portion 12 measured by the first pressure gauge 22. In addition, the second connection portion 14 is set so that, for example, the first raw material is not transported to the third pipe 16a.

Then, the second connection portion 14 is set so that, for example, the first raw material is transported to the third pipe 16a and not transported to the reaction chamber 4. In addition, the second raw material in the second storage container 32 is supplied to the inside of the reaction chamber 4 via the fourth pipe 38, the third connection portion 42, the third flow rate controller 36, the fifth pipe 40, and the fourth connection portion 44. Here, the second raw material stored inside the sixth pipe 46a, the sixth pipe 46b, or the fourth storage container 74 is further supplied to the inside of the reaction chamber 4 via the fourth flow rate controller 50, the third connection portion 42, and the third flow rate controller 36, the fifth pipe 40, and the fourth connection portion 44. For example, when the fourth flow rate controller 50 is a butterfly valve or the like, the opening degree of the butterfly valve or the like is appropriately controlled so that an appropriate amount of second raw material is transported to the reaction chamber 4 via the third flow rate controller 36. Here, for example, it is preferable to adjust the opening degree of the butterfly valve or the like by using the pressure of the sixth pipe 46b between the fourth flow rate controller 50 and the third connection portion 42 measured by the third pressure gauge 52. In addition, the fourth connection portion 44 is set so that, for example, the second raw material is not transported to the sixth pipe 46a.

The above operation is repeated to manufacture a semiconductor device.

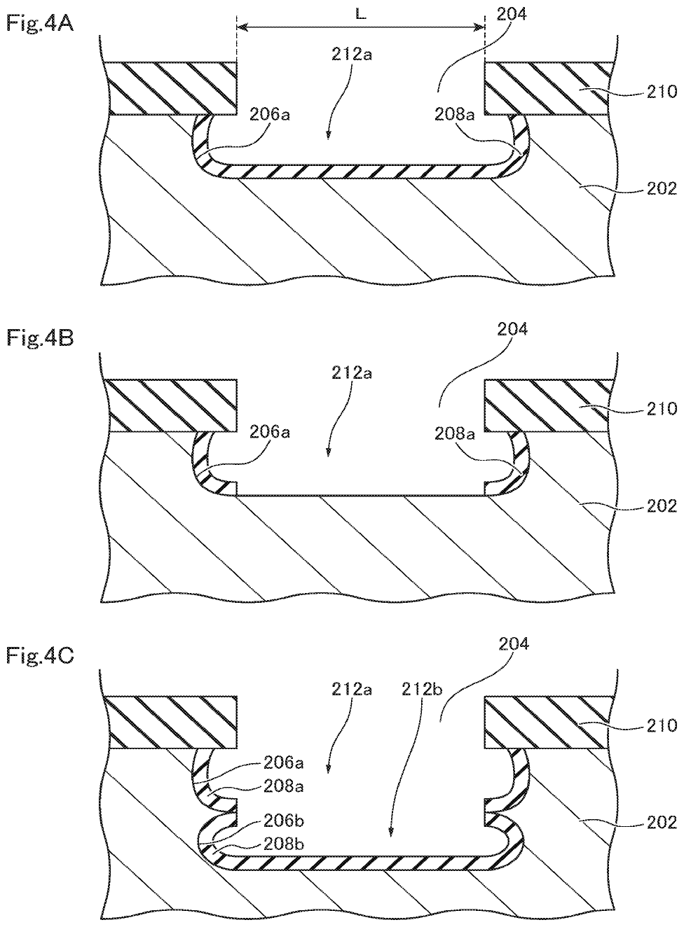

FIGS. 4A to 4C are schematic cross-sectional views showing an aspect of a semiconductor device manufacturing process using the semiconductor manufacturing apparatus 100 of embodiments. Sulfur hexafluoride (SF₆), which is a fluorine-supplied etching gas, is used as the first raw material. Octafluorocyclobutane (C₄F₈), which is a fluorinated hydrocarbon, is used as the second raw material.

A mask 210 having an opening 204 having a width L is provided on a semiconductor substrate 202 such as a silicon (Si) substrate disposed in the reaction chamber 4. A gap 212a is formed below the opening 204. A scallop 206a is formed on the side surface of the gap 212a. Here, octafluorocyclobutane (C₄F₈), which is the second raw material, is supplied into the reaction chamber 4. Then, a protective film 208a is formed on the side surface and the bottom surface of the gap 212a by using carbon tetrafluoride (CF₄)-based radicals formed from octafluorocyclobutane (C₄F₈) (FIG. 4A).

Then, sulfur hexafluoride (SF₆), which is the first raw material, is supplied into the reaction chamber 4. Then, a part of the protective film 208a formed on the bottom surface of the gap 212a is removed by anisotropic etching using F-based ions formed from sulfur hexafluoride (SF₆) (FIG. 4B).

Then, a gap 212b is formed below the bottom surface of the gap 212a by isotropic etching using F (fluorine)-based radicals formed from sulfur hexafluoride (SF₆), for example. A scallop 206b is formed on the side surface of the gap 212b. Then, a protective film 208b containing, for example, fluorocarbon is formed on the side surface and the bottom surface of the gap 212b by using carbon tetrafluoride (CF₄)-based radicals formed from octafluorocyclobutane (C₄F₈) (FIG. 4C).

By repeating the above steps, dicing of the semiconductor substrate 202 can be performed.

In addition, when trimethylaluminum (TMA), tetrakisdimethylamide titanium (TDMAT), or tetrakisdiethylaminohafnium (TDEAH) is used as the first raw material and water (H₂O) gas is used as the second raw material, it is possible to form an aluminum oxide film, a titanium oxide film, or a hafnium oxide film by using an atomic layer deposition (ALD) method.

Next, the function and effect of the semiconductor device of embodiments will be described.

A case is considered in which a semiconductor device is manufactured by supplying raw materials into a reaction chamber while switching the supply of a plurality of raw materials. In such a case, when an attempt to control the flow rate of the supplied raw materials to be constant is made by using a flow rate controller such as a mass flow controller, there is a problem that defects are likely to occur in the manufactured semiconductor device due to the delay of switching or the instability of the flow rate when switching the supply of raw materials.

In order to avoid such a problem, it is conceivable to switch between a pipe for supplying the raw materials to the reaction chamber and a pipe for discharging the raw materials by using a three-way valve or the like while controlling the amount of raw materials supplied to the reaction chamber to be constant by using the flow rate controller. However, since the amount of raw materials discharged increases, there is a problem that the efficiency of using the raw materials decreases.

Therefore, the semiconductor manufacturing apparatus of embodiments includes: the third pipe 16 connected to the first pipe 8 at the first connection portion 12 and connected to the second pipe 10 at the second connection portion 14; the first pump 18 for transporting the first raw material from the second pipe 10 to the first pipe 8, the first pump 18 having the first intake port 19a connected to the portion of the third pipe 16a connected to the second connection portion 14 and the first exhaust port 19b connected to the third pipe 16b connected to the first connection portion 12; and the second flow rate controller 20 for controlling the flow rate of the first raw material supplied from the first pump 18 to the first flow rate controller 6, the second flow rate controller 20 having the second inlet 21a connected to a portion of the third pipe 16b between the first connection portion 12 and the first pump 18, the second inlet 21a being connected to the first pump 18, the second flow rate controller having the second outlet 21b connected to a portion of the third pipe 16b between the first connection portion 12 and the first pump 18, and the second outlet 21b being connected to the first connection portion 12. Therefore, the first raw material planned to be discharged from the second connection portion 14 can be supplied to the reaction chamber 4 again. As a result, it is possible to provide a semiconductor manufacturing apparatus having high raw material use efficiency.

Similarly, the semiconductor manufacturing apparatus of embodiments includes: the sixth pipe 46 connected to the fourth pipe 38 at the third connection portion 42 and connected to the fifth pipe 40 at the fourth connection portion 44; the second pump 48 for transporting the second raw material from the fifth pipe 40 to the fourth pipe 38, the second pump 48 having the second intake port 49a connected to the portion of the sixth pipe 46a connected to the fourth connection portion 44 and the second exhaust port 49b connected to the sixth pipe 46b connected to the third connection portion 42; and the fourth flow rate controller 50 for controlling the flow rate of the second raw material supplied from the second pump 48 to the third flow rate controller 36, the fourth flow rate controller 50 having the fourth inlet 51a connected to a portion of the sixth pipe 46b between the third connection portion 42 and the second pump 48, the fourth inlet 51a being connected to the second pump 48, the fourth flow rate controller 50 having the fourth outlet 51b connected to a portion of the sixth pipe 46b between the third connection portion 42 and the second pump 48, and the fourth outlet 51b being connected to the third connection portion 42. Therefore, the second raw material planned to be discharged from the fourth connection portion 44 can be supplied to the reaction chamber 4 again. As a result, it is possible to provide a semiconductor manufacturing apparatus having high raw material use efficiency.

The semiconductor manufacturing apparatus of embodiments further includes: the seventh pipe 62 that can be connected to the third pipe 16b between the first pump 18 and the second flow rate controller 20 and discharges the first raw material to the outside of the third pipe 16; and the first adjustor 64 that has the fifth inlet 65a and the fifth outlet 65b, the fifth inlet 65a is connected to the seventh pipe 62, and the first adjustor 64 adjusts the amount of the first raw material discharged to the seventh pipe 62. Therefore, when the pressure inside the third pipe 16 is too high, the first raw material can be discharged from the third pipe 16. As a result, it is possible to suppress the failure of the semiconductor manufacturing apparatus.

The semiconductor manufacturing apparatus of embodiments further includes: the eighth pipe 66 that can be connected to the sixth pipe 46 between the second pump 48 and the fourth flow rate controller 50 and discharges the second raw material to the outside of the sixth pipe 46; and the second adjustor 68 that has the sixth inlet 69a and the sixth outlet 69b, the sixth inlet 69a is connected to the eighth pipe 66, and the second adjustor 68 adjusts the amount of the second raw material discharged to the eighth pipe 66. Therefore, when the pressure inside the sixth pipe 46 is too high, the second raw material can be discharged from the sixth pipe 46. As a result, it is possible to suppress the failure of the semiconductor manufacturing apparatus.

The semiconductor manufacturing apparatus of embodiments further includes the third storage container 72. Therefore, a larger amount of first raw material can be supplied from the second connection portion 14 to the reaction chamber 4 again via the first connection portion 12. As a result, it is possible to provide a semiconductor manufacturing apparatus having higher raw material use efficiency.

The semiconductor manufacturing apparatus of embodiments further includes the fourth storage container 74. Therefore, a larger amount of second raw material can be supplied from the fourth connection portion 44 to the reaction chamber 4 again via the third connection portion 42. As a result, it is possible to provide a semiconductor manufacturing apparatus having higher raw material use efficiency.

The case where the first raw material is a fluorine-supplied etching gas and the second raw material is a fluorinated hydrocarbon is suitable for dicing a semiconductor substrate, such as a silicon (Si) substrate. In particular, it is preferable that the first raw material is sulfur hexafluoride (SF₆) and the second raw material is octafluorocyclobutane (C₄F₈). In addition, in this case, the volume of sulfur hexafluoride (SF₆) used is smaller than the volume of octafluorocyclobutane (C₄F₈) used. Therefore, the internal volume of the third storage container 72 is preferably smaller than the volume of the fourth storage container 74.

According to the semiconductor manufacturing apparatus of embodiments, it is possible to provide a semiconductor manufacturing apparatus having high raw material use efficiency.

While certain embodiments have been described, these embodiments have been presented by way of example only, and are not intended to limit the scope of the inventions. Indeed, the semiconductor manufacturing apparatus described herein may be embodied in a variety of other forms; furthermore, various omissions, substitutions and changes in the form of the devices and methods described herein may be made without departing from the spirit of the inventions. The accompanying claims and their equivalents are intended to cover such forms or modifications as would fall within the scope and spirit of the inventions.

What is claimed is:

1. A semiconductor manufacturing apparatus, comprising:
a first storage container storing a first raw material and having a first container outlet;
a reaction chamber;
a first flow rate controller adjusting a flow rate of the first raw material transported from the first container outlet of the first storage container to the reaction chamber and having a first inlet and a first outlet;
a first pipe connecting the first container outlet of the first storage container and the first inlet of the first flow rate controller to each other and having a first connection portion;
a second pipe connecting the first outlet of the first flow rate controller and the reaction chamber to each other and having a second connection portion having a first flow path switching valve;
a third pipe connected to the first pipe at the first connection portion and connected to the second pipe at the second connection portion;
a first pump having a first intake port connected to a portion of the third pipe connected to the second connection portion, the first pump having a first exhaust port connected to a portion of the third pipe connected to the first connection portion and the first pump transporting the first raw material from the second pipe to the first pipe; and
a second flow rate controller having a second inlet connected to a portion of the third pipe between the first connection portion and the first pump, the second inlet being connected to the first pump, the second flow rate controller having a second outlet connected to a portion of the third pipe between the first connection portion and the first pump, the second outlet being connected to the first connection portion and the second flow rate controller controlling the flow rate of the first raw material supplied from the first pump to the first flow rate controller.

2. The semiconductor manufacturing apparatus according to claim 1, further comprising:
a second storage container storing a second raw material and having a second container outlet;
a third flow rate controller adjusting a flow rate of the second raw material transported from the second container outlet of the second storage container to the reaction chamber and having a third inlet and a third outlet;
a fourth pipe connecting the second container outlet of the second storage container and the third inlet of the third flow rate controller to each other and having a third connection portion;
a fifth pipe connecting the third outlet of the third flow rate controller and the reaction chamber to each other and having a fourth connection portion having a second flow path switching valve;
a sixth pipe connected to the fourth pipe at the third connection portion and connected to the fifth pipe at the fourth connection portion;
a second pump having a second intake port connected to a portion of the sixth pipe connected to the fourth connection portion, the second pump having a second exhaust port connected to a portion of the sixth pipe connected to the third connection portion and the second pump transporting the second raw material from the fifth pipe to the fourth pipe; and
a fourth flow rate controller having a fourth inlet connected to a portion of the sixth pipe between the third connection portion and the second pump, the fourth inlet being connected to the second pump, the fourth flow rate controller having a fourth outlet connected to a portion of the sixth pipe between the third connection portion and the second pump, the fourth outlet being connected to the third connection portion and the fourth flow rate controller controlling the flow rate of the second raw material supplied from the second pump to the third flow rate controller.

3. The semiconductor manufacturing apparatus according to claim 1, further comprising:
a seventh pipe connectable to a portion of the third pipe between the first pump and the second flow rate controller and discharging the first raw material to outside of the third pipe; and
a first adjustor having a fifth inlet connected to the seventh pipe and a fifth outlet connected to a ninth pipe and the first adjustor adjusting an amount of the first raw material discharged to the seventh pipe.

4. The semiconductor manufacturing apparatus according to claim 2, further comprising:
an eighth pipe connectable to a portion of the sixth pipe between the second pump and the fourth flow rate controller and discharging the second raw material to outside of the sixth pipe; and
a second adjustor having a sixth inlet connected to the eighth pipe and a sixth outlet connected to a ninth pipe and the second adjustor adjusting an amount of the second raw material discharged to the eighth pipe.

5. The semiconductor manufacturing apparatus according to claim 1, further comprising:
a third storage container having a third container inlet connected to a portion of the third pipe between the first pump and the second flow rate controller, the third container inlet being connected to the first pump, the third storage container having a third container outlet connected to a portion of the third pipe between the first pump and the second flow rate controller and the third container outlet being connected to the second flow rate controller.

6. The semiconductor manufacturing apparatus according to claim 2, further comprising:
a fourth storage container having a fourth container inlet connected to a portion of the sixth pipe between the second pump and the fourth flow rate controller, the fourth container inlet being connected to the second pump, the fourth storage container having a fourth container outlet connected to a portion of the sixth pipe between the second pump and the fourth flow rate controller and the fourth container outlet being connected to the fourth flow rate controller.

7. The semiconductor manufacturing apparatus according to claim 2,
wherein the first raw material is a fluorine-supplied etching gas, and
the second raw material is a fluorinated hydrocarbon.

8. The semiconductor manufacturing apparatus according to claim 4,
wherein the first raw material is a fluorine-supplied etching gas, and
the second raw material is a fluorinated hydrocarbon.

9. The semiconductor manufacturing apparatus according to claim 6,
wherein the first raw material is a fluorine-supplied etching gas, and
the second raw material is a fluorinated hydrocarbon.

10. The semiconductor manufacturing apparatus according to claim 2,
wherein the first raw material is sulfur hexafluoride (SF₆), and
the second raw material is octafluorocyclobutane (C₄F₈).

11. The semiconductor manufacturing apparatus according to claim 4,
wherein the first raw material is sulfur hexafluoride (SF₆), and
the second raw material is octafluorocyclobutane (C₄F₈).

12. The semiconductor manufacturing apparatus according to claim 6,
wherein the first raw material is sulfur hexafluoride (SF₆), and
the second raw material is octafluorocyclobutane (C₄F₈).

13. The semiconductor manufacturing apparatus according to claim 2, further comprising:
a third storage container provided in the third pipe between the first pump and the second flow rate controller; and
a fourth storage container provided in the sixth pipe between the second pump and the fourth flow rate controller,
wherein the first raw material is sulfur hexafluoride (SF₆), the second raw material is octafluorocyclobutane (C₄F₈), and
an internal volume of the third storage container is smaller than an internal volume of the fourth storage container.

14. The semiconductor manufacturing apparatus according to claim 4, further comprising:
a third storage container provided in the third pipe between the first pump and the second flow rate controller; and
a fourth storage container provided in the sixth pipe between the second pump and the fourth flow rate controller,
wherein the first raw material is sulfur hexafluoride (SF₆), the second raw material is octafluorocyclobutane (C₄F₈), and
an internal volume of the third storage container is smaller than an internal volume of the fourth storage container.
